(19) United States
(12) Patent Application Publication
(10) Pub. No.: US 2026/0173573 A1
(43) Pub. Date: Jun. 18, 2026

(54) ABSORBER, SOLAR CELL AND PROCESS FOR PRODUCING AN ABSORBER

(71) Applicant: HANWHA Q CELLS GMBH, Bitterfeld-Wolfen (DE)

(72) Inventors: Stefan HARTNAUER, Bitterfeld-Wolfen (DE); Lukas KEGELMANN, Bitterfeld-Wolfen (DE); Enrico JARZEMBOWSKI, Bitterfeld-Wolfen (DE); Fabian FERTIG, Bitterfeld-Wolfen (DE)

(21) Appl. No.: 19/104,398

(22) PCT Filed: Aug. 17, 2023
(86) PCT No.: PCT/DE2023/100610

§ 371 Date: Apr. 1, 2025

(30) Foreign Application Priority Data
Aug. 18, 2022 (DE) 10 2022 120 943.1

(51) Int. Cl. H10F 77/169; H10F 10/161; H10F 77/12; H10F 77/20

(52) U.S. Cl. CPC H10F 77/1699; H10F 10/161; H10F 77/126; H10F 77/211

(57) ABSTRACT

An absorber for a solar cell that has an empirical formula (Cs,AZ)Pbl₃, (Cs,AZ)Pb(l, Br)₃, (Cs,AZ)Pb(l, Cl)₃ or (Cs,AZ)Pb(l, Br, Cl)₃ and a perovskite structure, where AZ represents azetidinium. The invention further relates to a solar cell including the absorber. The invention further relates to a process for producing the absorber, comprising: a) providing a substrate, b) thermally evaporating Csl and/or CsBr and/or CsCl to form a first vapor jet produced from a first evaporation source, c) thermally evaporating Pbl₂ and/or PbBr₂ and/or PbCl₂ to form a second vapor jet produced from a second evaporation source, d) thermally evaporating AZI with AZI=azetidine hydroiodide or azetidinium iodide to form a third vapor jet which is produced from a third evaporation source, where steps b), c) and d) are performed simultaneously such that the first, second and third vapor jets overlap, such that the absorber is formed on the substrate.

### RELATED APPLICATIONS

The present application is a National Phase entry of PCT Application No. PCT/DE2023/100610, filed Aug. 17, 2023, which claims priority to German Patent Application No. 10 2022 120 943.1, filed Aug. 18, 2022, the disclosures of which are hereby incorporated by reference herein in their entirety.

### FIELD OF THE INVENTION

The invention relates to an absorber, to a solar cell, and to a process for producing an absorber. More particularly, the invention relates to an absorber having a perovskite structure, to a solar cell comprising the absorber, and to a process for producing an absorber of this kind.

### BACKGROUND OF THE INVENTION

Absorbers for solar cells having a perovskite structure are known. In the simplest case, the formation of the perovskite structure through condensation on a substrate occurs via the equation:

$$AX ( g ) + {BX}_{2} ( g ) \to A B {X}_{3} ( s ) , \qquad ( 1 )$$

when the two starting materials AX and BX₂ in gaseous form, denoted by (g), react to give a product ABX₃ in solid form, denoted by(s), and the product is deposited on the substrate. For example, where A=CH₃NH₃⁺, B=Pb²⁺, and X=halogen ion such as chloride, bromide or iodide, the reaction of gaseous methylammonium halide and gaseous lead (II) iodide results in the formation of methylammonium lead trihalide in solid form.

In a further development, it is possible to use a plurality of components of the same type, in which case the above equation (1) changes to:

$$AX ( g ) + {A}^{′} X ( g ) + {BX}_{2} ( g ) \to ( A , {A}^{′} ) {BX}_{3} ( s ) or \qquad ( 2 )$$

$${AX}^{′} ( g ) + {A}^{′} X ( g ) + {BX}_{2} ( g ) \to ( A , {A}^{′} ) {B ( X , {X}^{′} )}_{3} ( s ) or \qquad ( 3 )$$

$${AX}^{′} ( g ) + {AX}^{′′} ( g ) + {A}^{′} X ( g ) + {BX}_{2} ( g ) \to ( A , {A}^{′} ) {B ( X , {X}^{′} , {X}^{′′} )}_{3} ( s ) . \qquad ( 4 )$$

In this methodology, material compositions essentially selected from PbI₂ and/or PbBr₂ and/or PbCl₂ for BX₂ where B=Pb²⁺ and X=iodide or bromide or chloride, and CsI and/or CsBr and/or CsCl for AX or AX′ or AX″ where A=Cs⁺ and X=iodide or bromide or chloride and X′=bromide or iodide or chloride and X″=bromide or iodide or chloride, wherein X, X′ and X″ are each different, even when each has been selected from the same group of halides, undergo wet-chemical processing by co-evaporation with the organic components MAI (methylammonium iodide) and/or MABr (methylammonium bromide) and/or MACl (methylammonium chloride) or FAI (formamidinium iodide) and/or FaBr (formamidinium bromide) and/or FACl (formamidinium chloride), where A′=MA (methylammonium) or FA (formamidinium). In accordance with equations (2) or (3) or (4) and depending on the starting material used, this then results in the formation of (CsMA)PbI₃, (CsMA)Pb(I,Br)₃, (CsMA)Pb(I,Cl)₃, (CsMA)Pb(Br,Cl)₃, (CsMA)Pb(I,Br,Cl)₃, (CsMA)PbBr₃, (CsMA)PbCl₃, (CsFA)PbI₃, (CsFA)Pb(I,Br)₃, (CsFA)Pb(I,Cl)₃, (CsFA)Pb(Br,Cl)₃, (CsFA)Pb(I,Br,Cl)₃, (CsFA)PbBr₃ or (CsFA)PbCl₃ in the form of so-called organic metal halide perovskites. The processes for producing these absorbers generally include wet-chemical methods such as spin coating. At present, development is still largely on a laboratory scale. There is therefore a need for an absorber for a solar cell that can be produced on an industrial scale.

### SUMMARY

It is an object of the invention to provide an absorber, a solar cell, and a process for producing an absorber that can be provided on an industrial scale.

According to the invention, this object is achieved by an absorber having the features of claim 1, a solar cell having the features of claim 3, and a process having the features of claim 5. Advantageous developments and modifications are specified in the dependent claims.

The invention is based on processing an absorber by a co-evaporation process, said absorber having a novel perovskite structure. The absorber is CsAZPbI₃, CsAZPb(I,Br)₃, CsAZPb(I,Cl)₃ or CsAZPb(I,Br,Cl)₃, where AZ=azetidinium having the molecular formula C₃H₈N⁺. The perovskite structure is in this case a crystal structure formed from Cs—, AZ—, and Pb— cations and I— and optionally Br— and optionally Cl— anions.

The invention relates to the novel compositions of the absorber of the invention that can be produced by co-evaporation. The co-evaporation takes place through simultaneous thermal evaporation of the absorber starting materials in the form of CsI (cesium iodide) and/or CsBr (cesium bromide) and/or CsCl (cesium chloride) with PbI₂ (lead (II) iodide) and/or PbBr₂ (lead (II) bromide) and/or PbCl₂ (lead (II) chloride) and AZI (azetidine hydroiodide or azetidinium iodide) to form the absorber having a crystal structure in the form of a perovskite structure. The absorber is a hybrid material of organic and inorganic materials. It is an organic metal halide perovskite in which, in sunlight, electrons can be released from their bound state and energized, while at the same time leaving behind positively charged defects as “holes”. The absorber is preferably intended for use in a solar cell.

The basic concept of the invention is to form a perovskite structure from starting materials that are more suitable for evaporation processes than those already known from the prior art. This can be based on consideration of the vapor pressures of the materials themselves or on the vapor pressures of the individual ions of the molecules. The selection of AZI as starting material for the production of the absorber of the invention is based in particular on the following parameters: vapor pressure of the individual components in the form of AZ=azetidine and HI=hydrogen iodine, size of the molecule, and the dipole moment/polarity of the molecule. The CsAZPbI₃, CsAZPb(I,Br)₃, CsAZPb(I,Cl)₃ or CsAZPb(I,Br,Cl)₃ absorber deposited in the co-evaporation process crystallizes directly in the relevant perovskite phase. The thermal stability and electrical properties (photoluminescence) of CsAZPbI₃, CsAZPb(I,Br)₃, CsAZPb(I,Cl)₃ or CsAZPb(I,Br,Cl) show comparable and in some cases better results compared to laboratory-produced perovskite absorbers of the prior art.

The perovskite structure represents a crystal structure in which octahedra of in this case Pb(X, optionally X′, optionally X″)₆, where X=iodide, optionally X′=bromide, optionally X″=chloride, form a structure having holes in which Cs and AZ cations are intercalated. The perovskite structure is preferably based on a component AX, in the form of CsI, and/or AX′, in the form of CsBr, and/or AX″, in the form of CsCl, these compounds being present in a high proportion of preferably >60% and forming a basic structure, and a component A′X present in a low proportion of <40% that is incorporated into the basic structure and causes distortion of the crystal structure. The absorber therefore has a distorted perovskite structure, since the Cs and AZ cations, which have radii/diameters of different size, are intercalated in the holes.

According to the invention, A′X=AZI (azetidine hydroiodide or azetidinium iodide) is employed as organic component in the process, which results in crystallization and desired thermal stability of the perovskite structure when used in the co-evaporation process. AZI, on account of its lower vapor pressure, can be evaporated in a more controlled manner than established organic perovskite starting materials such as MAI and FAI. Moreover, the absorber having a perovskite structure in the form of CsAZPbI₃, CsAZPb(I,Br)₃, CsAZPb(I,Cl)₃ or CsAZPb(I,Br,Cl)₃ is itself more stable than comparable absorbers having a perovskite structure of the prior art, especially under thermal stress. For example, at 100° C. the absorber is stable for more than 10 hours and does not show any degradation.

Furthermore, the absorber of the invention is relatively stable in air and can be stored in air for 3 days without visible changes and/or degradation. In electrical characterization by photoluminescence (PL), the absorber of the invention shows good results comparable to those of laboratory-produced perovskite structures of the prior art. The absorber of the invention also shows no visible changes in the PL measurement after thermal stress (>10 hours) or storage in air (max. 3 days). In contrast to the laboratory-produced perovskite absorbers of the prior art, the absorber of the invention is stable even when exposed to increased solar radiation, for example 10 suns, without any change in a measured spectrum.

The invention relates to an absorber having a perovskite structure of the formula (Cs,AZ)PbI₃, (Cs,AZ)Pb(I, Br)₃, (Cs,AZ)Pb(I, Cl)₃ or (Cs,AZ)Pb(I, Br, Cl)₃, where AZ denotes azetidinium. The absorber is inexpensive and can be made thin.

The perovskite structure is stabilized by mixed crystal formation with the incorporation of two or more components A, A′ of the same type, for example according to equation (2), (3) or (4) where A=Cs⁺ and A′=azetidinium, in which case in equations (2), (3) and (4) X is iodide, X′ bromide, and X″ chloride. Preferably, the Pb and X, such as I ions, and optionally X′, such as Br ions, and optionally X″, such as Cl ions, form a Pb(X, optionally X′, optionally X″)₆ octahedron structure and the Cs and AZ ions are intercalated in this structure. This creates a distorted perovskite structure. One reason for the distorted perovskite structure is the different radii/diameters of the Cs and AZ cations.

The absorber is preferably formed as a thin film and has a layer thickness of <1 μm, preferably in the range from 200 to 800 nm, more preferably in the range from 300 to 700 nm, even more preferably in the range from 400 to 600 nm. Alternatively preferably, the absorber may be formed as a wafer.

The invention further relates to a solar cell including the absorber of the invention. The solar cell includes an inexpensive, highly efficient absorber, which can be made thin.

In a preferred embodiment, the solar cell is formed as a thin-film solar cell. Alternatively or additionally preferably, the solar cell is designed as a tandem solar cell. The thickness of a thin-film solar cell varies from a few nanometers (nm) to several tens of micrometers (μm), whereas a wafer solar cell has a thickness of up to 250 μm. Thin-film solar cells are therefore a hundred times thinner than wafer solar cells.

Preferably the solar cell has
a front-side metalization as front-side electrode,
a hole conductor adjacent thereto that is designed to transport positively charged holes to the front-side electrode,
the absorber of the invention, which is adjacent to the hole conductor and absorbs the radiation from sunlight, wherein positive (“holes”) and negative charge carriers (electrons) are generated,
an electron conductor adjacent to the absorber that transfers the electrons to a rear-side electrode, and
a rear-side metalization as rear-side electrode.

The front side is a side facing the light, and the rear side is a side facing away from the light.

Alternatively preferably, the solar cell has
a front-side metalization as front-side electrode,
an electron conductor adjacent thereto that transfers the electrons to the front-side electrode,
the absorber of the invention, which is adjacent to the hole conductor and absorbs the radiation from sunlight, wherein positive (“holes”) and negative charge carriers (electrons) are generated,
a hole conductor adjacent to the absorber that is designed to transport positively charged holes to the rear-side electrode, and
a rear-side metalization as rear-side electrode.

Preferably, the solar cell is designed as a tandem solar cell. Preferably, the tandem solar cell has at least two subcells, more preferably two subcells. Preferably, the subcell present in the absorber of the invention is an upper subcell of the tandem solar cell, the upper subcell being the subcell closest to the incident light. The tandem solar cell may be fabricated such that the subcells are deposited monolithically directly on top of one another. Alternatively, the tandem solar cell may be fabricated such that the subcells are produced separately from one another and mounted on top of one another electrically separately.

Preferably, the tandem solar cell has the following structure in the specified sequence:
a front-side metalization,
an electrically conductive layer such as an ITO layer (transparent indium tin oxide layer) for example with a layer thickness of 100 nm,
a buffer/electron conductor layer such as a SnO₂ layer for example with a layer thickness of 20 nm,
a passivating and hole-blocking layer such as a LiF/C60 layer for example having a layer thickness in the LiF layer of 1 nm and a layer thickness in the C60 layer of 18 nm,
the absorber of the invention for example with a layer thickness of about 500 nm,
a hole conductor layer such as NiO/2PACz layer (nickel oxide/[2-(9H-carbazol-9-yl)ethyl]phosphonic acid layer),
a further electrically conductive layer such as an ITO layer for example with a layer thickness of 20 nm,
a TOPCon layer (charge-carrier-selective contact layer, containing TOPCon=Tunnel Oxide Passivated Contact),
a further absorber such as a silicon substrate, for example a p-type or n-type Cz-Si substrate,
a p⁺ or n⁺ doped silicon layer,
a rear-side passivation,
a rear-side metalization, where the rear-side metalization has local contacts through the rear-side passivation with the substrate.

The invention further relates to a process for producing the absorber of the invention, comprising:
a) providing a substrate,
b) thermally evaporating CsI and/or CsBr and/or CsCl to form a first vapor jet that is generated from a first evaporation source,
c) thermally evaporating PbI₂ and/or PbBr₂ and/or PbCl₂ to form a second vapor jet that is generated from a second evaporation source,
d) thermally evaporating AZI, where AZI=azetidine hydroiodide or azetidinium iodide, to form a third vapor jet that is generated from a third evaporation source,
steps b), c) and d) being carried out simultaneously such that the first vapor jet, the second vapor jet, and the third vapor jet overlap at least partially, resulting in the formation of the absorber of the invention on the provided substrate.

The simultaneous execution of steps b), c) and d) means that the deposition of the absorber is executed in a single step. The at least partial overlap of the vapor jets is essential for the process.

The temperatures for the thermal evaporation of the starting materials are different: In a preferred embodiment, the temperature for the thermal evaporation of CsI and/or CsBr and/or CsCl in step b) is between 450 and 600° C. The temperature for the thermal evaporation of PbI₂ and/or PbBr₂ and/or PbCl₂ in step c) is preferably between 220 and 350° C. The temperature for the thermal evaporation of AZI in step d) is preferably between 100 and 250° C.

In a preferred embodiment, the process is carried out under high vacuum. The high vacuum is preferably in the pressure region of <10⁻⁵ mbar.

The mixing ratio of CsI and/or CsBr and/or CsCl to AZI is preferably in the range of from 75%-90% to 10%-25%. In other words, the mixing ratio of CsI to AZI and/or CsBr to AZI is in a mixing ratio range between a first mixing ratio of 75% to 25% and a second mixing ratio of 90% to 10%. Preferably, PbI₂ and/or PbBr₂ and/or PbCl₂ and CsI and/or CsBr and/or CsCl and the organic component AZI are reacted to form CsIAZPbI₃, CsAZPb(I,Br)₃, CsAZPb(I,Cl)₃ or CsAZPb(I,Br,Cl)₃ in a mixing ratio of CsI and/or CsBr and/or CsCl and AZI of from 75%-90% to 10%-25%. This ensures the formation of a perovskite structure that is based on component AX, in the form of CsI, and/or AX′, in the form of CsBr, and/or AX″, in the form of CsCl, these compounds being present in a high proportion of preferably >60%, and on the component A′X in the form of AZI, which is present in a low proportion of <40%. An advantage is that the proportion of the organic component is significantly lowered compared to other organic components such as FAI. In addition, the vapor pressure of AZI is lower than that of FAI and therefore more suitable for evaporation processes, consequently the use of AZI instead of FAI allows higher throughputs and lower plant costs.

The absorber is preferably formed as a thin film. Alternatively preferably, the absorber is formed as a wafer.

In a preferred embodiment, the coating of the substrate with the absorber is carried out statically. Alternatively preferably, the coating of the substrate with the absorber is carried out in an inline production facility. Both variants permit industrial-scale production of the absorber.

### BRIEF DESCRIPTION OF THE DRAWINGS

The invention will be elucidated below on the basis of exemplary embodiments with reference to the figures. In the schematic figures, which are not to scale:

FIG. 1 shows an outline representation of a process according to the invention;

FIG. 2 shows an outline representation of a noninventive absorber;

FIG. 3 shows an outline representation of an absorber according to the invention; and

FIG. 4 shows a solar cell according to the invention.

### DETAILED DESCRIPTION

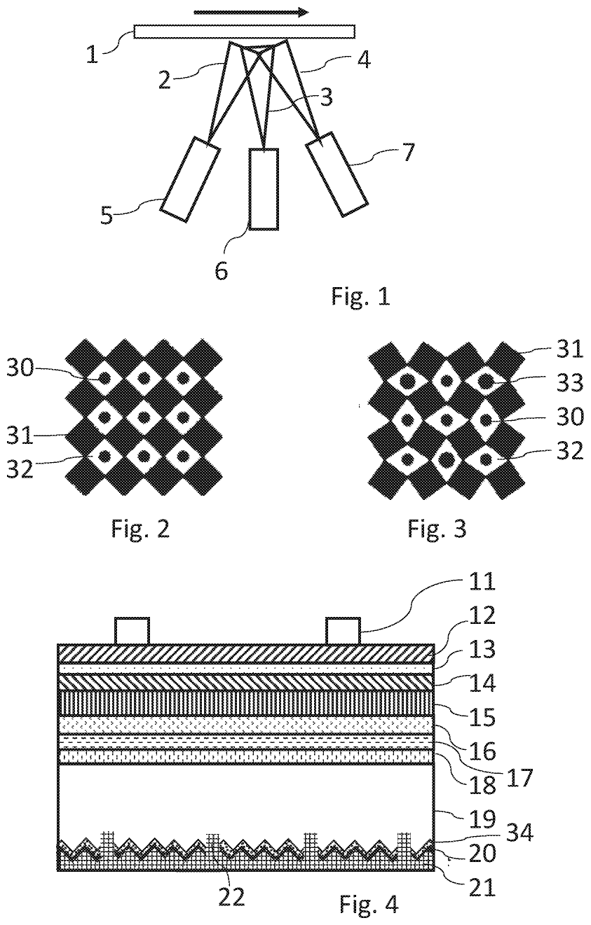

FIG. 1 shows an outline representation of a process according to the invention. The process for producing an absorber comprises: A step a) of providing a substrate 1. The process is carried out in an inline production plant (not shown) in which the substrate 1 is transported in a direction indicated by an arrow. Steps b) thermally evaporating CsI and/or CsBr and/or CsCl to form a first vapor jet 4 that is generated from a first evaporation source 7, c) thermally evaporating PbI₂ and/or PbBr₂ and/or PbCl₂ to form a second vapor jet 3 that is generated from a second evaporation source 6, and d) thermally evaporating AZI, where AZI=azetidine hydroiodide or azetidinium iodide, to form a third vapor jet 2 that is generated from a third evaporation source 5 are carried out. Steps b), c), and d) are carried out simultaneously such that the first vapor jet 4, the second vapor jet 3, and the third vapor jet 2 overlap at least partially, resulting in the formation of an absorber (not shown) with a perovskite structure having the formula (Cs,AZ)PbI₃, (Cs,AZ)Pb(I, Br)₃, (Cs,AZ)Pb(I, Cl)₃ or (Cs,AZ)Pb(I, Br, Cl)₃ on the provided substrate 1.

FIG. 2 shows an outline representation of a noninventive absorber. The absorber has a perovskite structure with the formula CsPbI₃, where Pb and Cs ions are cations and I ions are anions. The crystal structure is formed as a basic structure composed of PbI₆ octahedra 31 in which the Cs cations 30 are intercalated in holes 32 between PbI₆ octahedra 31. The holes 32 and the PbI₆ octahedra 31 are the same size and arranged in a regular manner.

FIG. 3 shows an outline representation of an absorber according to the invention. The absorber has a crystal structure in the form of a mixed structure of PbI₆ octahedra 31 in which Cs⁺ 30 and AZ⁺ 33 are intercalated in holes 32 between PbI₆ octahedra 31. The Cs cations 30 have a diameter that is smaller than the diameter of the AZ cations 33. Compared to the basic structure shown in FIG. 2, the mixed structure has distorted holes 32, i.e, the holes that form are not all of equal size and the PbI₆ octahedra are not evenly arranged, as a result of which the crystal structure is distorted. The absorber may be produced according to the process shown in FIG. 1.

FIG. 4 shows a solar cell according to the invention. It is designed as a tandem solar cell and has the following structure in the specified sequence:
a front-side metalization 11,
an electrically conductive layer 12 such as an ITO layer with a layer thickness of 100 nm,
a buffer/electron conductor layer 13 such as a SnO₂ layer with a layer thickness of 20 nm,
a passivating and hole-blocking layer 14 such as a LiF/C60 layer having a layer thickness in the LiF layer of 1 nm and a layer thickness in the C60 layer of 18 nm,
an absorber 15 shown in FIG. 3 with a layer thickness of about 500 nm,
a hole conductor layer 16 such as NiO/2PACz layer,
a further electrically conductive layer 17 such as an ITO layer with a layer thickness of 20 nm,
a TOPCon layer 18,
a further absorber 19 such as a silicon substrate in the form of a p-type or n-type Cz-Si substrate,
a p⁺ or n⁺ doped silicon layer 34,
a rear-side passivation 20,
a rear-side metalization 21, where the rear-side metalization 21 has local contacts 22 through the rear-side passivation 20 with the further absorber 19.

### LIST OF REFERENCE NUMERALS

1 Substrate
2 Third vapor jet
3 Second vapor jet
4 First vapor jet
5 Third evaporation source
6 Second evaporation source
7 First evaporation source
11 Front-side metalization
12 Electrically conductive layer
13 Electron conductor layer
14 Hole blocking layer
15 Absorber
16 Hole conductor layer
17 Further conductive layer
18 TOPCon
19 Further absorber
20 Rear-side passivation
21 Rear-side metalization
22 Local contact
30 Cs⁺
31 PbI₆ octahedron
32 Hole
33 AZ⁺
34 Silicon layer

1. An absorber for a solar cell having a molecular formula of (Cs,AZ)PbI₃, (Cs,AZ)Pb(I, Br)₃, (Cs,AZ)Pb(I, Cl)₃ or (Cs,AZ)Pb(I, Br, Cl)₃ and a perovskite structure, where AZ stands for azetidinium.

2. The absorber as claimed in claim 1, wherein the Pb, I and optionally Br and optionally Cl ions form a basic structure and that the Cs and AZ ions are intercalated in the basic structure.

3. A solar cell, comprising an absorber as claimed in claim 1.

4. The solar cell as claimed in claim 3, wherein the solar cell is designed as a thin-film solar cell and/or as a tandem solar cell.

5. A process for producing an absorber as claimed in claim 1, comprising:
a) providing a substrate,
b) thermally evaporating CsI and/or CsBr and/or CsCl to form a first vapor jet that is generated from a first evaporation source,
c) thermally evaporating PbI₂ and/or PbBr₂ and/or PbCl₂ to form a second vapor jet that is generated from a second evaporation source,
d) thermally evaporating AZI, where AZI=azetidine hydroiodide or azetidinium iodide, to form a third vapor jet that is generated from a third evaporation source,
steps b), c) and d) being carried out simultaneously such that the first vapor jet, the second vapor jet, and the third vapor jet overlap at least partially, resulting in formation of the absorber on the provided substrate.

6. The process as claimed in claim 5, wherein a temperature for the thermal evaporation of CsI and/or CsBr and/or CsCl in step b) is between 450 and 600° C. and/or that a temperature for the thermal evaporation of PbI₂ and/or PbBr₂ and/or PbCl₂ in step c) is between 220 and 350° C. and/or that a temperature for the thermal evaporation of AZI in step d) is between 100 and 250° C.

7. The process as claimed in claim 5, wherein the process is carried out under high vacuum.

8. The process as claimed in claim 5 wherein the mixing ratio of CsI and/or CsBr and/or CsCl to AZI is in a mixing ratio range between a first mixing ratio of 75% to 25% and a second mixing ratio of 90% to 10%.

9. The process as claimed in claim 5 wherein the absorber is formed as a thin film or as a wafer.

10. The process as claimed in claim 5 wherein the coating of the substrate with the absorber is carried out statically or the coating of the substrate with the absorber is carried out in an inline production facility.

11. The process as claimed in claim 7, wherein the high vacuum is in a pressure region of <10⁻⁵ mbar.
